(19) United States
(12) Patent Application Publication
(10) Pub. No.: US 2025/0185174 A1
(43) Pub. Date: Jun. 5, 2025

(54) FLEXIBLE WIRE BOARD, LIGHT SOURCE DEVICE AND PROJECTOR

(71) Applicant: Sharp NEC Display Solutions, Ltd., Tokyo (JP)

(72) Inventor: Yusuke TANI, Tokyo (JP)

(21) Appl. No.: 19/042,976

(22) Filed: Jan. 31, 2025

Related U.S. Application Data
(63) Continuation of application No. PCT/JP2022/034252, filed on Sep. 13, 2022.

(51) Int. Cl. H05K 1/18; G03B 21/20; H05K 1/11; H05K 1/14; H10H 20/857

(52) U.S. Cl. CPC H05K 1/181; G03B 21/2013; H05K 1/118; H05K 1/147; H10H 20/857; H05K 2201/10106; H05K 2201/10151

(57) ABSTRACT

A flexible wire board having a plurality of wire layers arranged in a thickness direction, and for connecting light sources to a power supply and an information processor, including a plurality of first connectors for connecting to the plurality of light sources, a second connector for connecting to the power supply, a third connector for connecting to the information processor, a plurality of power supply wires that extend from the plurality of first connectors to the second connector, and a plurality of signal wires that extend from the plurality of first connectors to the third connector. The power supply wires and the signal wires are provided in wire layers different from each other.

### TECHNICAL FIELD

The present disclosure relates to a flexible wire board, a light source device and a projector.

### BACKGROUND ART

Patent Document 1 discloses a projector including a light source device including a plurality of light sources (semiconductor laser).

### CITATION LIST

### Patent Document

### [Patent Document 1]

Japanese Unexamined Patent Application, First Publication No. 2015-213057

### SUMMARY OF INVENTION

### Technical Problem

Incidentally, each light source may be connected to a plurality of connection destinations such as a power supply configured to supply power to a light source and an information processor configured to acquire and process various pieces of information indicating the status of a light source from a light source. When a plurality of light sources have a plurality of connection destinations, a wiring structure for connecting them tends to be complicated, and as a result, it may become difficult to assemble a projector including a light source device.

The present invention has been made in view of the above circumstances and an object of the present invention is to provide a flexible wire board, a light source device and a projector that can improve the ease of assembling of a projector.

### Solution to Problem

A first aspect of the present invention provides a flexible wire board having a plurality of wire layers arranged in a thickness direction, and for connecting a plurality of light sources each having a thermistor to a power supply configured to supply power to the light sources and an information processor configured to process information output from the thermistors, the flexible wire board including: a plurality of first connectors for connecting to the plurality of light sources; a second connector for connecting to the power supply; a third connector for connecting to the information processor; a plurality of power supply wires that extend from the plurality of first connectors to the second connector; and a plurality of signal wires that extend from the plurality of first connectors to the third connector. The power supply wires and the signal wires are provided in wire layers different from each other.

A second aspect of the present invention provides a light source device including the flexible wire board, the plurality of light sources, and a heat dissipation plate part having a mounting surface on which the plurality of light sources are mounted. The flexible wire board includes a plurality of first parts in which the plurality of first connectors are provided in one-to-one correspondence therewith, a second part which is positioned at an interval with respect to the plurality of first parts and in which the second connector and the third connector are provided, and a plurality of connection parts that connect each of the plurality of first parts and the second part. The first parts are disposed on the mounting surface in an overlapping manner by connecting the plurality of first connectors to the plurality of light sources. The connection parts and the second part extend in a direction away from the mounting surface.

A third aspect of the present invention provides a light source device including the flexible wire board, the plurality of light sources, a heat dissipation plate part having a mounting surface on which the plurality of light sources are mounted, and an optical system attached to the mounting surface. The flexible wire board includes a plurality of first parts in which the plurality of first connectors are provided in one-to-one correspondence therewith, a second part which is positioned at an interval with respect to the plurality of first parts and in which the second connector and the third connector are provided, and a plurality of connection parts that connect each of the plurality of first parts and the second part. The first parts are disposed on the mounting surface in an overlapping manner by connecting the plurality of first connectors to the plurality of light sources. The second part is fixed to the optical system.

A fourth aspect of the present invention provides a projector including the flexible wire board, the plurality of light sources, the power supply, the information processor, and a housing in which the flexible wire board, the light source, the power supply and the information processor are accommodated. The first part of the flexible wire board in which the plurality of first connectors are provided is connected to the light source. The second part of the flexible wire board in which the second connector and the third connector are provided is fixed to the optical system.

### Advantageous Effects of Invention

According to the present invention, it is possible to improve the ease of assembling of a projector.

### BRIEF DESCRIPTION OF DRAWINGS

FIG. 1 is a perspective view showing an appearance of a projector according to one embodiment of the present invention.

FIG. 2 is a perspective view showing a state in which an upper cover of a housing is removed in the projector of FIG. 1.

FIG. 3 is a perspective view showing the positions of a light source device, a power supply, an information processor and a blower fan on a bottom plate part of the housing in FIG. 2.

FIG. 4 is a perspective view showing the light source device and the blower fan in FIGS. 1 to 3.

FIG. 5 is a perspective view showing a state in which an optical system is removed from the light source device of FIG. 4.

FIG. 6 is a front view of the configuration of FIG. 5 when viewed from the side of a mounting surface of a heat dissipation plate part.

FIG. 7 is a front view showing a light source and a flexible wire board in the configuration of FIGS. 5 and 6.

FIG. 8 is a rear view showing the light source and the flexible wire board of FIG. 7.

FIG. 9 is a side view showing the light source and the flexible wire board of FIGS. 7 and 8.

FIG. 10 is a diagram showing the layout of power supply wires and signal wires of the flexible wire board in FIGS. 7 to 9.

FIG. 11 is a diagram showing the layout of power supply wires of the flexible wire board in FIG. 10.

FIG. 12 is a rear view showing the layout of signal wires of the flexible wire board in FIG. 10.

FIG. 13 is a diagram schematically showing the cross section of the flexible wire board of FIGS. 10 to 12.

FIG. 14 is a block diagram showing a partial configuration of a projector according to one embodiment of the present invention.

FIG. 15 is a diagram showing a flexible substrate according to another embodiment of the present invention.

### DESCRIPTION OF EMBODIMENTS

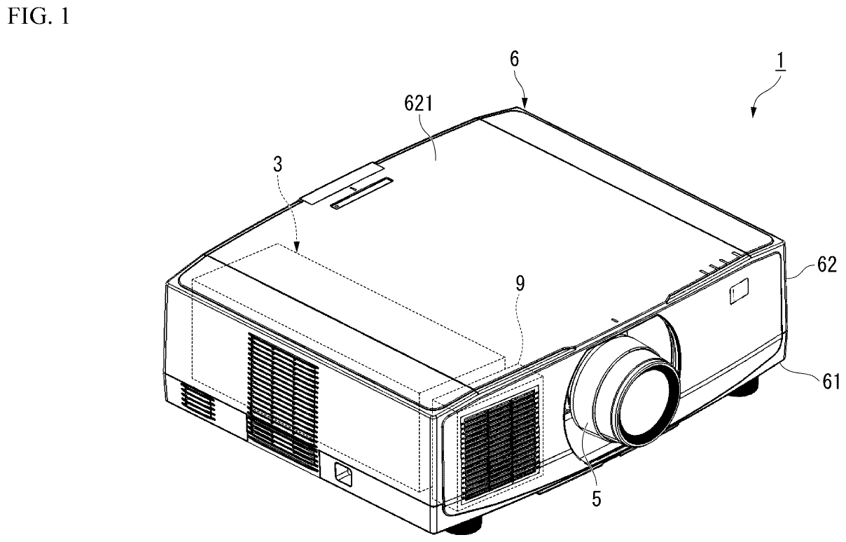

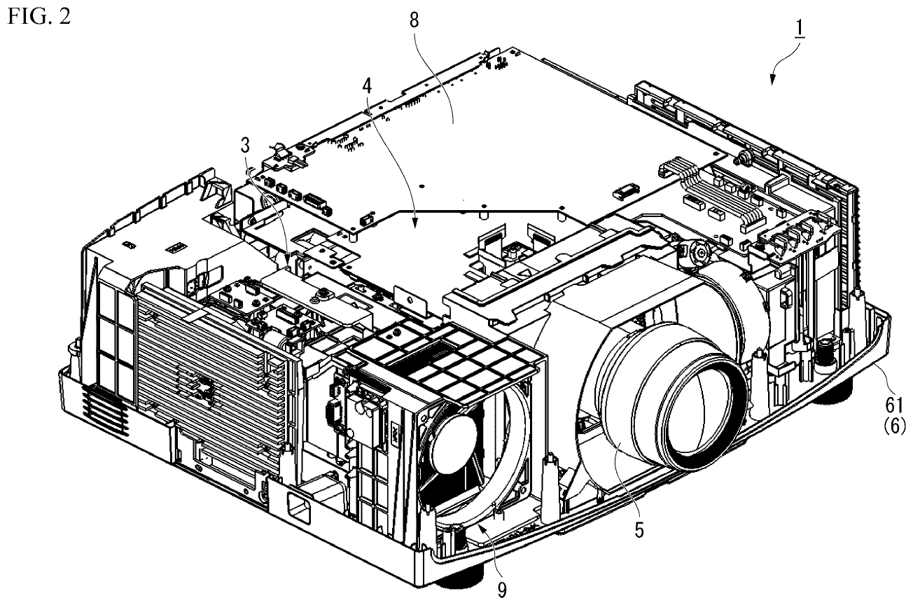

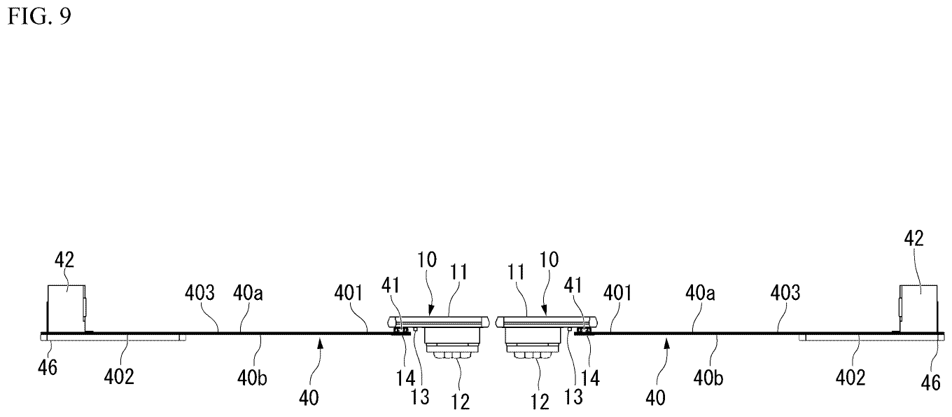

Hereinafter, one embodiment of the present invention will be described with reference to FIGS. 1 to 14.

As shown in FIGS. 1 to 3, a projector 1 according to the present embodiment is a device that projects image light (video) onto a display surface such as a screen. The projector 1 includes a light source device 3, an image light forming device 4, a projection device 5, a housing 6, a power supply 7, an information processor 8, and a blower fan 9.

The image light forming device 4 generates image light based on light output from the light source device 3 to be described below. Although not shown, the image light forming device 4 includes a light modulation element such as a digital micromirror device (DMD) or a liquid crystal panel and an electronic component that controls the light modulation element.

The projection device 5 magnifies the image light output from the image light forming device 4 and projects it onto a display surface such as a screen.

The housing 6 accommodates the light source device 3, the image light forming device 4, the projection device 5, the power supply 7, the information processor 8 and the blower fan 9. The housing 6 includes the light source device 3, the image light forming device 4, the projection device 5, the power supply 7, a bottom plate part 61 on which the information processor 8 and the blower fan 9 are mounted, the light source device 3, the image light forming device 4, the projection device 5, the power supply 7, and an upper cover 62 that covers the information processor 8 and the blower fan 9 from above. The upper cover 62 includes a top plate part 621 that faces the bottom plate part 61.

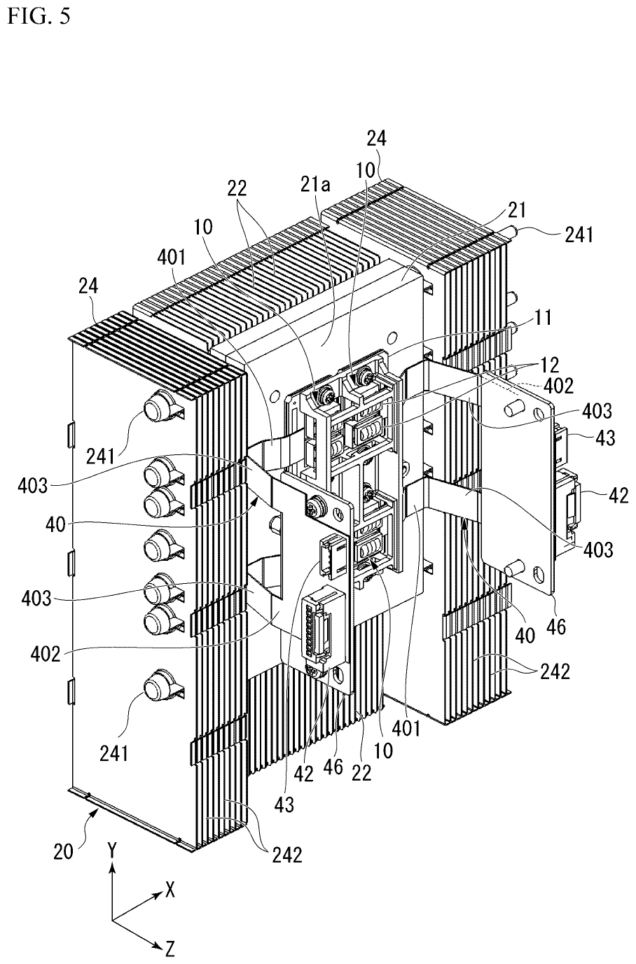

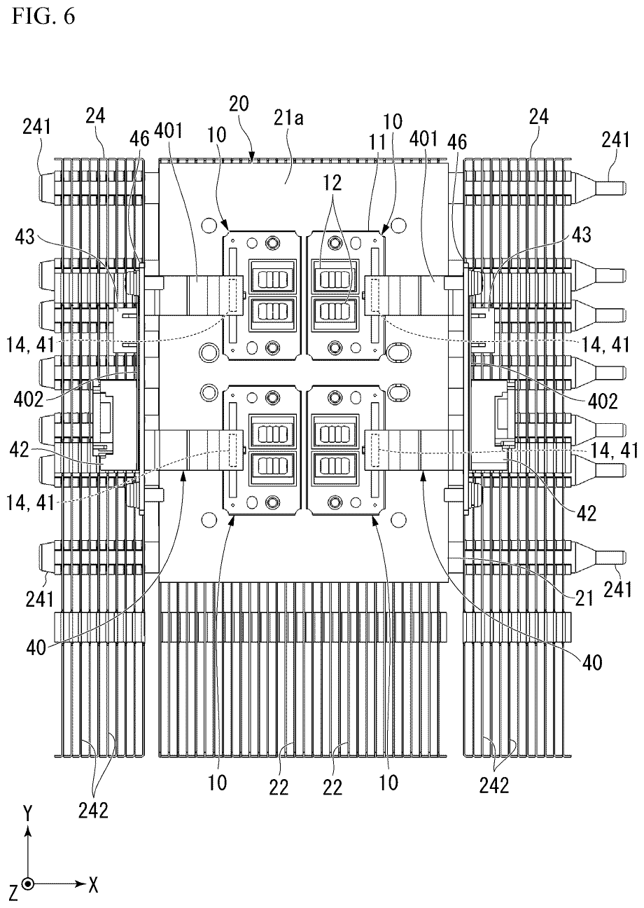

The power supply 7 mainly supplies power to a light source 10 (refer to FIGS. 5 and 6, etc.) of the light source device 3 to be described below. The power supply 7 is disposed on the side of the bottom plate part 61 of the housing 6.

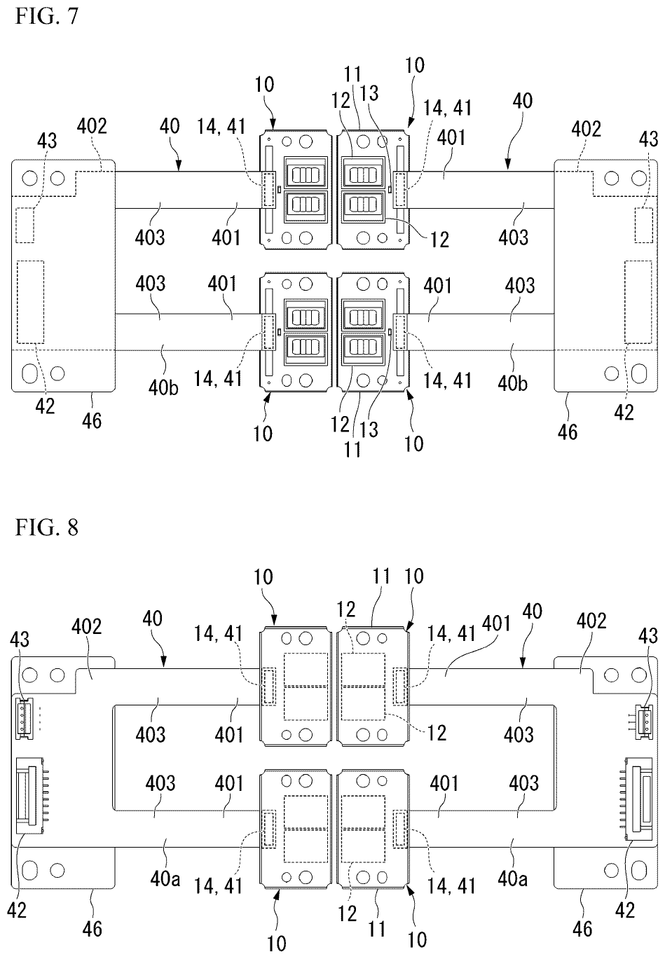

The information processor 8 processes information output from a thermistor 13 (refer to FIG. 7, etc.) of the light source 10 to be described below. The information processor 8 of the present embodiment controls operations of the power supply 7 and the blower fan 9 based on the information. The information processor 8 is disposed on the side of the top plate part 621 of the housing 6 with respect to the power supply 7.

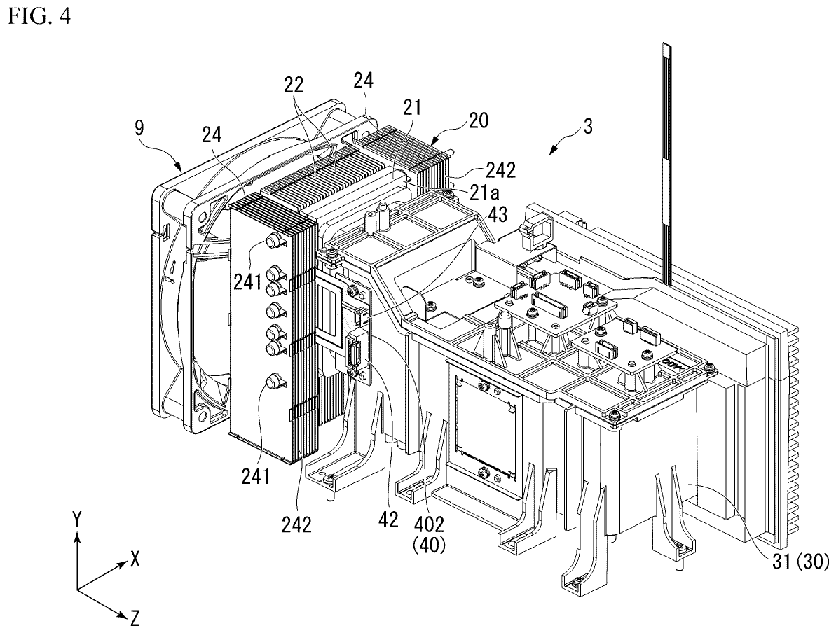

As shown in FIGS. 4 to 6, the light source device 3 includes the light source 10, a heat dissipator 20, an optical system 30, and a flexible wire board 40.

The light source 10 shown in FIGS. 5 and 6 emits light. The light source device 3 of the present embodiment includes a plurality of light sources 10 (four light sources in the illustrated example). As shown in FIGS. 6 to 9, each light source 10 includes a substrate 11, a light emitting element 12 mounted on the substrate 11, the thermistor 13 and a connection connector 14.

The light emitting element 12 may be, for example, a light emitting diode (LED), and it is a laser diode in the present embodiment. The light emitting element 12 of the present embodiment emits laser light in a blue wavelength range. That is, the light source 10 of the present embodiment is a laser substrate. The number of light emitting elements 12 included in the light source 10 may be two as shown in the illustrated example, but the number is not limited thereto.

The thermistor 13 measures the temperature of the light source 10. Electrical wires (not shown) connecting the light emitting element 12 and the thermistor 13 to the connection connector 14 are formed on the substrate 11. The flexible wire board 40 to be described below is connected to the connection connector 14.

In the light source 10 of the present embodiment, when viewed from the thickness direction of the substrate 11, the thermistor 13 is positioned between the light emitting element 12 and the connection connector 14. Therefore, two power supply wires (not shown) formed on the substrate 11 and connecting the light emitting element 12 and the connection connector 14 are positioned on both sides of a signal wire (not shown) formed on the substrate 11 and connecting the thermistor 13 and the connection connector 14. As a result, when viewed from the thickness direction of the substrate 11, a signal terminal (not shown) of the connection connector 14 connected to the thermistor 13 is positioned between two power supply terminals (not shown) of the connection connector 14 connected to the light emitting element 12.

As shown in FIGS. 4 to 6, the heat dissipator 20 is provided to cool the light source 10, and includes a heat dissipation plate part 21, a plurality of heat dissipation fins 22, and an extended heat dissipator 24.

As shown in FIGS. 5 and 6, the heat dissipation plate part 21 is formed to be generally flat, and has a mounting surface 21a on which a plurality of light sources 10 are mounted. Specifically, the substrate 11 of the light source 10 is disposed on the mounting surface 21a in an overlapping manner. The substrate 11 may be in direct contact with the mounting surface 21a, but for example, a heat conducting grease may be interposed between the substrate 11 and the mounting surface 21a to improve heat transfer from the substrate 11 to the heat dissipation plate part 21. The heat dissipation plate part 21 is formed of a highly conductive material, for example, copper.

In FIGS. 4 to 6, a first direction along the mounting surface 21a is indicated by the X-axis direction, and a second direction perpendicular to the first direction along the mounting surface 21a is indicated by the Y-axis direction. In addition, the orthogonal direction perpendicular to the mounting surface 21a is indicated by the Z-axis direction. The Z-axis direction corresponds to the plate thickness direction of the heat dissipation plate part 21.

The plurality of heat dissipation fins 22 are provided on the surface of the heat dissipation plate part 21 facing opposite to the mounting surface 21a in the plate thickness direction. The plurality of heat dissipation fins 22 are each formed into a plate shape whose thickness direction is the first direction (X-axis direction) along the mounting surface 21a of the heat dissipation plate part 21, and are arranged at intervals in the first direction. In FIGS. 5 and 6, the plurality of heat dissipation fins 22 protrude only from one side (negative Y-axis direction side) of the heat dissipation plate part 21 in the second direction (Y-axis direction), but they may protrude from, for example, both sides of the heat dissipation plate part 21, or for example, may not protrude.

The extended heat dissipator 24 is positioned on both sides of the heat dissipation plate part 21 in the first direction. Here, for example, the extended heat dissipator 24 may be positioned only on one side of the heat dissipation plate part 21 in the first direction.

The extended heat dissipator 24 includes a heat pipe 241 and a plurality of heat dissipation fins 242 attached to the heat pipe 241. The heat pipe 241 penetrates the heat dissipation plate part 21 in the first direction, and extends from both ends of the heat dissipation plate part 21. A plurality of heat pipes 241 (seven heat pipes in the illustrated example) are arranged in the second direction.

The plurality of heat dissipation fins 242 of the extended heat dissipator 24 are each formed into a plate shape whose thickness direction is the first direction. The plurality of heat dissipation fins 242 are arranged at intervals in the first direction on both sides of the heat dissipation plate part 21 in the first direction. The heat pipes 241 are attached to the plurality of heat dissipation fins 242 so that they penetrate the heat dissipation fins 242 in the thickness direction.

In the heat dissipator 20, when air flows in the orthogonal direction (Z-axis direction) to the plurality of heat dissipation fins 22 and the extended heat dissipator 24, air can flow between the heat dissipation fins 22 and 242 adjacent to each other. Thereby, heat transferred from the plurality of light sources 10 to the heat dissipation fins 22 via the heat dissipation plate part 21 and heat transferred to the plurality of heat dissipation fins 242 via the heat dissipation plate part 21 and the heat pipe 241 can be dissipated, that is, the plurality of light sources 10 can be cooled.

As shown in FIG. 4, the optical system 30 is attached to the mounting surface 21a of the heat dissipation plate part 21 on which the light source 10 is disposed. The optical system 30 appropriately processes light (blue light) from the light source 10 and emits white light to the image light forming device 4. The optical system 30 includes a plurality of optical system components (not shown) for appropriately processing light from the light source 10 and a case 31 for accommodating these optical system components.

The case 31 of the optical system 30 has an opening (not shown) that allows the light emitted from the light source 10 to enter the inside of the case 31. When the edge of the opening of the case 31 is brought into close contact with the area around the light source 10 on the mounting surface 21a, the light source 10 can be covered by the case 31. Thereby, dust on the outside of the case 31 can be inhibited or prevented from reaching the light source 10.

The flexible wire board 40 shown in FIGS. 5 to 9 is provided to connect the light source 10 to the power supply 7 and the information processor 8. The flexible wire board 40 is formed into a sheet shape extending in one direction (the left to right direction in FIGS. 7 to 9) and is formed such that it can be easily bent in the thickness direction. The flexible wire board 40 includes a plurality of first connectors 41, a second connector 42, and a third connector 43.

The plurality of first connectors 41 are terminals for connecting to the plurality of light sources 10. The number of first connectors 41 corresponds to the number of light sources 10 connected to the same flexible wire board 40. In the present embodiment, the number of light sources 10 connected to the same flexible wire board 40 is two, but the present invention is not limited thereto. The first connector 41 is directly connected to the connection connector 14 of the light source 10.

The arrangement of power supply terminals and signal terminals in the first connector 41 corresponds to the arrangement of power supply terminals and signal terminals in the connection connector 14 of the light source 10 described above.

The second connector 42 is a terminal for connecting to the power supply 7. The second connector 42 is connected to an electrical wire (not shown) extending from the power supply 7. The third connector 43 is a terminal for connecting to the information processor 8. The third connector 43 is connected to an electrical wire (not shown) extending from the information processor 8.

The first to third connectors 41 to 43 are provided on a main surface 40a on one side of the flexible wire board 40 in the thickness direction.

The flexible wire board 40 includes a plurality of first parts 401 and a second part 402 positioned at intervals in one direction, and a plurality of connection parts 403 that connect each of these plurality of first parts 401 and a second part 402.

In the plurality of first parts 401 of the flexible wire board 40, each of the plurality of first connectors 41 described above is provided. In the second part 402 of the flexible wire board 40, the second and third connectors 42 and 43 described above are provided. In addition, in the second part 402, the second and third connectors 42 and 43 are arranged in the width direction (the vertical direction in FIGS. 7 and 8) of the flexible wire board 40. The width direction of the flexible wire board 40 is a direction perpendicular to the arrangement direction of the first parts 401 and the second part 402 (the left to right direction in FIGS. 7 and 8).

In the present embodiment, the plurality of first parts 401 and the plurality of connection parts 403 arranged in the extension direction (one direction) of the flexible wire board 40 are arranged at intervals in the width direction of the flexible wire board perpendicular to the extension direction. The numbers of first parts 401 and connection parts 403 in the same flexible wire board 40 are the same, and correspond to the number of first connectors 41 provided in the first part 401. In the illustrated example, since the number of first connectors 41 in the same flexible wire board 40 is two, the numbers of first parts 401 and connection parts 403 are also two.

In the second part 402 of the flexible wire board 40 in which the second and third connectors 42 and 43 are provided, a reinforcing plate 46 is provided in an overlapping manner. The reinforcing plate 46 increases the rigidity of the second part 402 of the flexible wire board 40 and prevents the second part 402 from being bent. The reinforcing plate 46 is provided on a main surface 40b on the other side of the flexible wire board 40 in an overlapping manner.

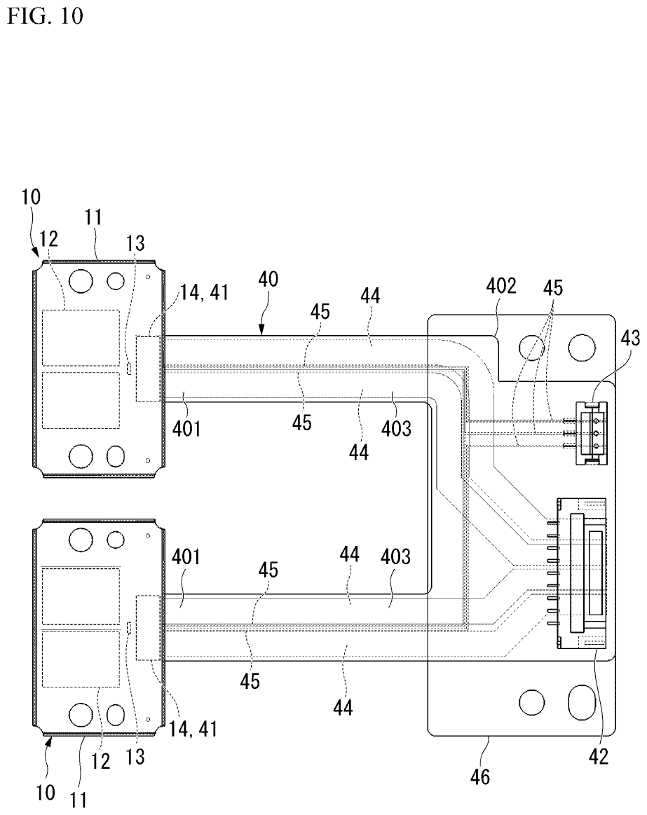

As shown in FIGS. 10 to 12, the flexible wire board 40 includes a plurality of power supply wires 44 and a plurality of signal wires 45.

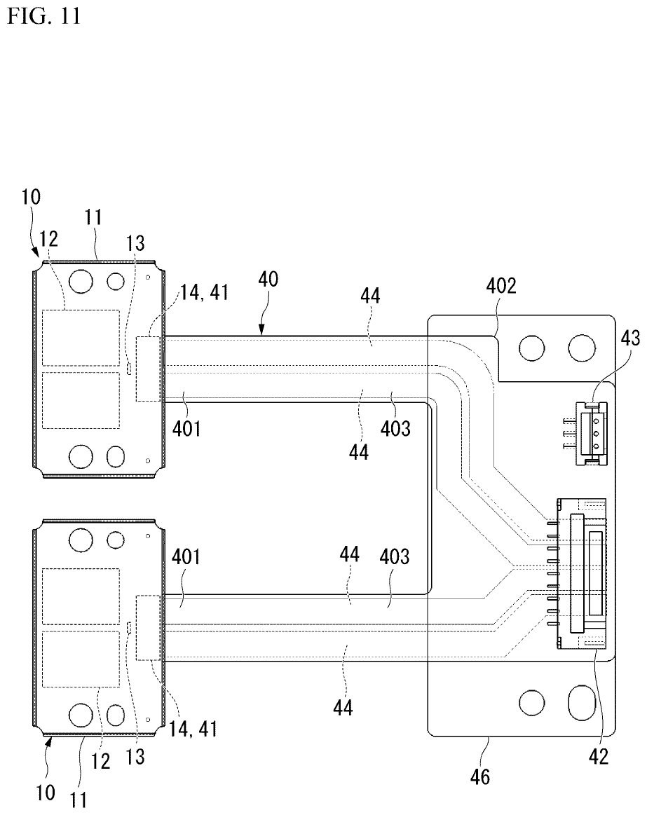

As shown in FIGS. 10 and 11, the plurality of power supply wires 44 extend from the plurality of first connectors 41 to the second connector 42. Each power supply wire 44 is formed wider than the signal wire 45 to be described below when viewed from the thickness direction of the flexible wire board 40. The number of power supply wires 44 extending from each first connector 41 is two. Twice as many power supply wires 44 as the number of first connectors 41 (two first connectors in the illustrated example) are connected to the second connector 42.

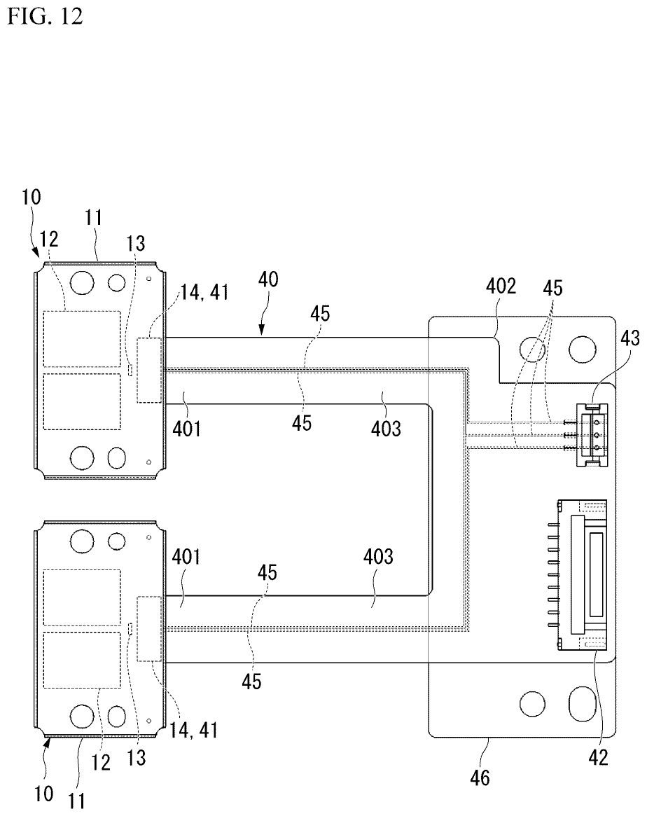

As shown in FIGS. 10 and 12, the plurality of signal wires 45 extend from the plurality of first connectors 41 to the third connector 43. The magnitude of the current flowing through the signal wire 45 is smaller than that of the current flowing through the power supply wire 44. Therefore, each signal wire 45 is formed thinner than the power supply wire 44 when viewed from the thickness direction of the flexible wire board 40. The number of signal wires 45 extending from each first connector 41 is two. One of the two signal wires 45 is for ground. The plurality of ground signal wires 45 extending from the plurality of first connectors 41 are integrated into one wire and then reach the third connector 43. Therefore, the signal wires 45 numbering one more than the first connectors 41 are connected to the third connector 43.

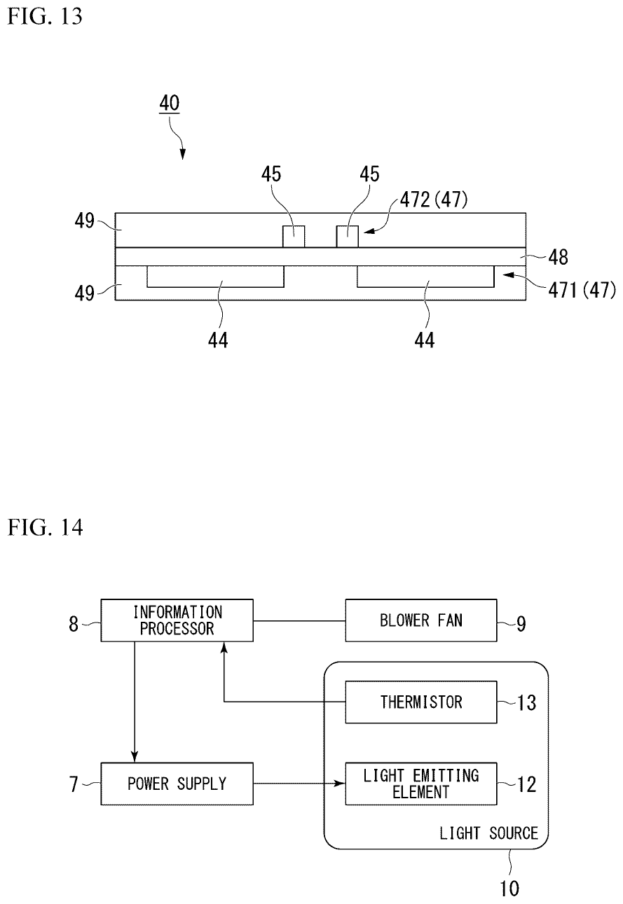

As shown in FIG. 13, the flexible wire board 40 has a plurality of wire layers 47 arranged in the thickness direction. For example, the flexible wire board 40 may be formed by stacking three or more wire layers 47, but in the present embodiment, the flexible wire board 40 is formed by stacking two wire layers 47. Specifically, the flexible wire board 40 has a base layer 48, two wire layers 47 (a first wire layer 471 and a second wire layer 472) formed on both sides of the base layer 48, and a coating layer 49 covering each of these two wire layers 47. The base layer 48 and the coating layer 49 are made of an electrically insulating material such as a polyimide, and the wire layer 47 is formed of a conductor such as copper.

The power supply wire 44 and the signal wire 45 described above are provided in different wire layers 47. In FIG. 13, the power supply wire 44 is provided in the first wire layer 471, and the signal wire 45 layer is provided in the second wire layer 472.

As shown in FIG. 10, in the present embodiment, in the first parts 401 and the connection parts 403 of the flexible wire board 40, the two power supply wires 44 and signal wires 45 extending from the same first connector 41 are positioned to correspond to two power supply terminals and signal terminals in the connection connector 14 of the light source 10. Specifically, the signal wire 45 extending from the same first connector 41 is positioned between two power supply wires 44 extending from the same first connector 41 in the width direction of the flexible wire board 40.

Next, the disposition of the flexible wire board 40 with respect to the light source 10, the heat dissipator 20 and the optical system 30 will be described.

As shown in FIGS. 5 and 6, the plurality of first parts 401 of the flexible wire board 40 are disposed on the mounting surface 21a in an overlapping manner by connecting two first connectors 41 to the connection connectors 14 of the two light sources 10 disposed on the mounting surface 21a of the heat dissipation plate part 21. Thus, the flexible wire board 40 is bent at the boundary part between the first part 401 and the connection part 403. Thereby, the plurality of connection parts 403 and the second part 402 of the flexible wire board 40 extend in a direction away from the mounting surface 21a (the positive Z-axis direction in FIGS. 5 and 6). In addition, in this state, the plurality of connection parts 403 of the flexible wire board 40 are arranged at intervals in the width direction of the flexible wire board 40.

Specifically, the plurality of first parts 401 of the flexible wire board 40 each extend in the first direction from the plurality of light sources 10 mounted on the mounting surface 21a toward the edge of the mounting surface 21a. Thus, the plurality of connection parts 403 and the second part 402 of the flexible wire board 40 extend in a direction away from the mounting surface 21a by bending the flexible wire board 40 at the edge of the mounting surface 21a in the first direction. Therefore, the flexible wire board 40 (particularly the plurality of connection parts 403 and the second part 402) does not overlap the extended heat dissipator 24 in the orthogonal direction (Z-axis direction). Here, the second and third connectors 42 and 43 provided in the second part 402 of the flexible wire board 40 overlap the extended heat dissipator 24 in the orthogonal direction (Z-axis direction). In addition, in this state, a plurality of connection parts 403 (two connection parts in the illustrated example) of the same flexible wire board 40 are arranged at intervals in the second direction.

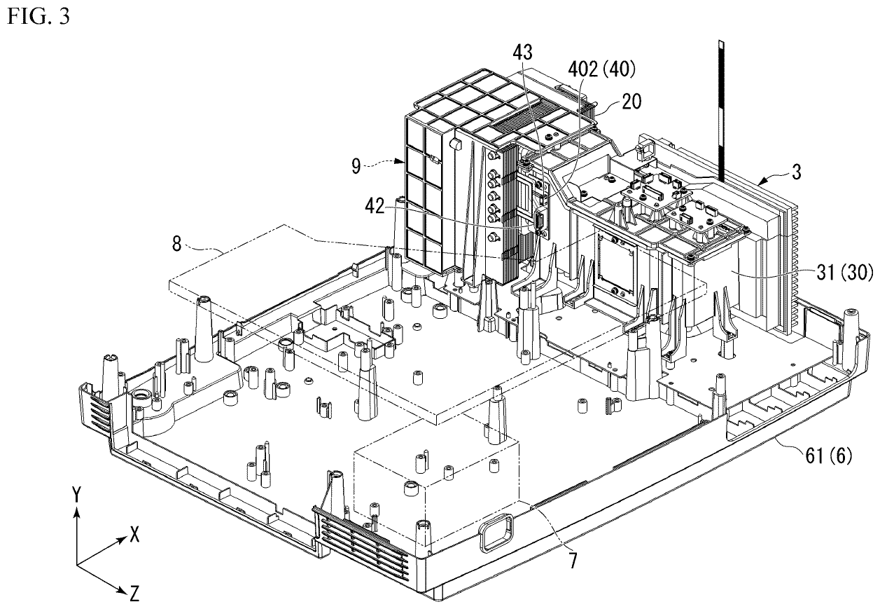

As shown in FIGS. 3 and 4, the second part 402 of the flexible wire board 40 is positioned outside the case 31 of the optical system 30 disposed on the mounting surface 21a of the heat dissipation plate part 21. Thus, the second part 402 of the flexible wire board 40 is fixed to the outer surface of the case 31 of the optical system 30.

When the second part 402 of the flexible wire board 40 is fixed to the optical system 30, the second connector 42 provided in the second part 402 is disposed on the side of the bottom plate part 61 of the housing 6, similarly to the power supply 7 described above. In addition, the third connector 43 provided in the second part 402 is disposed on the side of the top plate part 621 of the housing 6 with respect to the second connector 42 (refer to FIG. 1), similarly to the information processor 8 described above.

As shown in FIG. 4, the blower fan 9 is disposed to face the heat dissipation plate part 21 with the plurality of heat dissipation fins 22 therebetween and also to face the extended heat dissipator 24. The blower fan 9 blows air toward the plurality of heat dissipation fins 22 and the extended heat dissipator 24 in the orthogonal direction (Z-axis direction). The plurality of light sources 10 can be cooled by passing air between the heat dissipation fins 22 and 242 adjacent to each other according to air blowing from the blower fan 9.

Next, the control of operations of the power supply 7 and the blower fan 9 by the information processor 8 will be described mainly with reference to FIG. 14.

As shown in FIG. 14, the thermistors 13 of the plurality of light sources 10 measure the temperature of each light source 10 and output it to the information processor 8. The information processor 8 controls operations of the power supply 7 and the blower fan 9 based on the temperatures output from the plurality of thermistors 13. Specifically, the information processor 8 controls the voltage that is output from the power supply 7 and drives the light emitting element 12 of the light source 10 and the rotational speed of the blower fan 9 so that the temperature of the plurality of light sources 10 reaches a predetermined temperature or approaches a predetermined temperature. Here, “predetermined temperature” may be, for example, a temperature lower than the heat-resistant temperature of the light source 10.

For example, when the temperature measured by the thermistor 13 is higher than a predetermined temperature, the information processor 8 lowers the drive voltage of the light source 10 output from the power supply 7 or increases the rotational speed of the blower fan 9. By lowering the drive voltage of the light source 10 output from the power supply 7, the amount of heat generated in the light source 10 can be kept low. In addition, the light source 10 can be cooled more efficiently by increasing the rotational speed of the blower fan 9.

The flexible wire board 40 of the present embodiment includes the plurality of first connectors 41 connected to the plurality of light sources 10, a second connector 42 connected to the power supply 7, a third connector 43 connected to the information processor 8, the plurality of power supply wires 44 connecting the plurality of first connectors 41 and the second connector 42, and the plurality of signal wires 45 connecting the plurality of first connectors 41 and the third connector 43. Thereby, by using only one flexible wire board 40, the plurality of light sources 10 can be connected to the power supply 7 and the information processor 8 (that is, a plurality of connection destinations). This simplifies a wiring structure for connecting the plurality of light sources 10, the power supply 7 and the information processor 8. Therefore, it is possible to improve the ease of assembling of the projector 1.

In addition, in the flexible wire board 40 of the present embodiment, the power supply wire 44 and the signal wire 45 are provided in the wire layers 47 different from each other (the first and second wire layers 471 and 472). Thereby, the power supply wire 44 and the signal wire 45 can be easily laid out so that the power supply wire 44 and the signal wire 45 do not interfere with each other. In addition, the size (area) of the flexible wire board 40 when viewed from the thickness direction can be kept small.

In addition, in the flexible wire board 40 of the present embodiment, the reinforcing plate 46 is provided on the second part 402 in which the second and third connectors 42 and 43 are provided in an overlapping manner. Thereby, the reinforcing plate 46 can increase the rigidity of the second part 402 of the flexible wire board 40 and prevent the second part 402 from being bent.

In addition, in the flexible wire board 40 of the present embodiment, the plurality of first connectors 41 are provided in one-to-one correspondence with the plurality of first parts 401. In addition, the plurality of connection parts 403 are connected in one-to-one correspondence with the plurality of first parts 401. Therefore, compared to when the plurality of first connectors 41 are provided in a first part 401, the materials constituting the flexible wire board 40 (particularly the base layer 48 and the coating layer 49) can be saved, and the production cost of the flexible wire board 40 can be reduced. This effect is particularly effective when the plurality of first connectors 41 are positioned at intervals.

In addition, in the light source device 3 including the flexible wire board 40 of the present embodiment, when the plurality of first parts 401 of the flexible wire board in which the plurality of first connectors 41 are provided in one-to-one correspondence therewith are connected to the light source 10, they are disposed on the mounting surface 21a of the heat dissipation plate part 21 in an overlapping manner. In addition, the second part 402 of the flexible wire board 40 in which the second connector 42 and the third connector 43 are provided extends in a direction away from the mounting surface 21a.

Therefore, the second part 402 of the flexible wire board 40 can be prevented from overlapping the plurality of heat dissipation fins 22 and the extended heat dissipator 24 positioned outside the mounting surface 21a of the heat dissipation plate part 21 in the orthogonal direction (Z-axis direction). Thereby, the second part 402 of the flexible wire board 40 can prevent the blower fan 9 from obstructing the flow of air passing through the plurality of heat dissipation fins 22 and the extended heat dissipator 24, that is, can prevent cooling of the light source 10 from being obstructed.

In addition, in the light source device 3 including the flexible wire board 40 of the present embodiment, the second part 402 of the flexible wire board 40 including the second and third connectors 42 and 43 is fixed to the optical system 30 attached to the mounting surface 21a of the heat dissipation plate part 21. Therefore, compared to when the second part 402 of the flexible wire board 40 is fixed to the heat dissipator 20 including the heat dissipation plate part 21, the heat dissipator 20 can be made smaller. In addition, when the second part 402 of the flexible wire board 40 is fixed to the heat dissipator 20, it is possible to prevent the cooling performance of the light source 10 by the heat dissipator 20 from deteriorating.

In addition, in the projector 1 including the flexible wire board 40 of the present embodiment, the power supply 7 and the second connector 42 are disposed on the side of the bottom plate part 61 of the housing 6. In addition, the information processor 8 is disposed on the side of the top plate part 621 of the housing 6 that faces the bottom plate part 61 with respect to the power supply 7. In addition, the third connector 43 is disposed on the side of the top plate part 621 of the housing 6 with respect to the second connector 42. Therefore, an electrical wire connecting the second connector 42 and the power supply 7 and an electrical wire connecting the third connector 43 and the information processor 8 can be formed short. In addition, it is possible to prevent these electrical wires from becoming entangled.

While the embodiments of the present invention have been described above, the present invention is not limited to the embodiments, and can be appropriately changed without departing from the spirit and scope of the present invention.

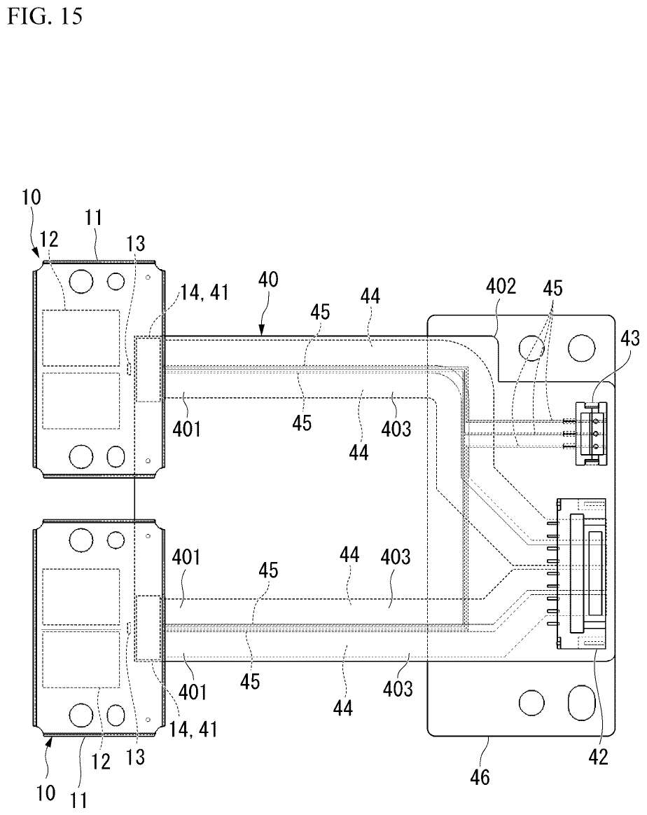

In the flexible wire board of the present invention, for example, as shown in FIG. 15, the numbers of first parts 401 and connection parts 403 may be one, and the plurality of first connectors 41 may be provided in a first part 401. In other words, the first part 401 and the connection part 403 do not have to be divided into a plurality of parts. With such a configuration, the same effects as in the above embodiment can be exhibited.

In the present invention, the heat dissipator 20 need only include at least the heat dissipation plate part 21.

In the present invention, the number of connection destinations of the light source 10 is not limited to two, that is, for the power supply 7 and the information processor 8, and may be, for example, three or more. In this case, the flexible wire board 40 need only include, when the number of light sources 10 is m (m: integer), and the number of connection destinations is n (n: integer), m first connectors 41, n connection destination connectors, and n types of connection wires that connect the first connectors 41 and the n connection destination connectors. Thus, n types of connection wires only need to be provided in wire layers different from each other. Here, the above “connection destination connectors” correspond to the second and third connectors 42 and 43 in the above embodiment. In addition, the “connection wires” correspond to the power supply wire 44 and the signal wire 45 in the above embodiment.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### REFERENCE SIGNS LIST

1 Projector
3 Light source device
6 Housing
7 Power supply
8 Information processor
10 Light source
13 Thermistor
20 Heat dissipator
21 Heat dissipation plate part
21a Mounting surface
30 Optical system
40 Flexible wire board
401 First part of flexible wire board 40
402 Second part of flexible wire board 40
403 Connection part of flexible wire board 40
41 First connector
42 Second connector
43 Third connector
44 Power supply wire
45 Signal wire
46 Reinforcing plate
47 Wire layer
61 Bottom plate part
621 Top plate part

What is claimed is:

1. A flexible wire board having a plurality of wire layers arranged in a thickness direction, and for connecting a plurality of light sources each having a thermistor to a power supply configured to supply power to the light sources and an information processor configured to process information output from the thermistors, the flexible wire board comprising:
a plurality of first connectors for connecting to the plurality of light sources;
a second connector for connecting to the power supply;
a third connector for connecting to the information processor;
a plurality of power supply wires that extend from the plurality of first connectors to the second connector; and
a plurality of signal wires that extend from the plurality of first connectors to the third connector,
wherein the power supply wires and the signal wires are provided in wire layers different from each other.

2. The flexible wire board according to claim 1, further comprising
a plurality of first parts in which the plurality of first connectors are provided in one-to-one correspondence therewith, a second part which is positioned at an interval with respect to the plurality of first parts and in which the second connector and the third connector are provided, and a plurality of connection parts that connect each of the plurality of first parts and the second part, and
wherein a reinforcing plate is provided on the second part in an overlapping manner.

3. The flexible wire board according to claim 1, further comprising
a plurality of first parts in which the plurality of first connectors are provided in one-to-one correspondence therewith, a second part which is positioned at an interval with respect to the plurality of first parts and in which the second connector and the third connector are provided, and a plurality of connection parts that connect each of the plurality of first parts and the second part,
wherein the plurality of first parts and the plurality of connection parts are arranged at intervals in a width direction of the flexible wire board perpendicular to the arrangement direction of the plurality of first parts and the second part, and
wherein the numbers of the first parts and connection parts correspond to the number of first connectors.

4. The flexible wire board according to claim 1,
wherein the signal wire is formed thinner than the power supply wire when viewed from the thickness direction of the flexible wire board.

5. The flexible wire board according to claim 1, further comprising
a plurality of first parts in which the plurality of first connectors are provided in one-to-one correspondence therewith, a second part which is positioned at an interval with respect to the plurality of first parts and in which the second connector and the third connector are provided, and a plurality of connection parts that connect each of the plurality of first parts and the second part,
wherein, in each of the plurality of first parts and the plurality of connection parts, the signal wire extending from a first connector is positioned between the two power supply wires extending from the same first connector in a width direction of the flexible wire board perpendicular to the arrangement direction of the plurality of first parts and the second part.

6. The flexible wire board according to claim 1, further comprising
a first part in which the plurality of first connectors are provided, a second part which is positioned at an interval with respect to the first part and in which the second connector and the third connector are provided, and one connection part that connects the first part and the second part,
wherein a reinforcing plate is provided on the second part in an overlapping manner.

7. A light source device, comprising:
a flexible wire board;
a plurality of light sources; and
a heat dissipation plate part having a mounting surface on which the plurality of light sources are mounted,
wherein the flexible wire board has a plurality of wire layers arranged in a thickness direction, and for connecting a plurality of light sources each having a thermistor to a power supply configured to supply power to the light sources and an information processor configured to process information output from the thermistors,
wherein the flexible wire board comprises:
a plurality of first connectors for connecting to the plurality of light sources;
a second connector for connecting to the power supply;
a third connector for connecting to the information processor;
a plurality of power supply wires that extend from the plurality of first connectors to the second connector; and
a plurality of signal wires that extend from the plurality of first connectors to the third connector,
wherein the power supply wires and the signal wires are provided in wire layers different from each other,
wherein the flexible wire board includes a plurality of first parts in which the plurality of first connectors are provided in one-to-one correspondence therewith, a second part which is positioned at an interval with respect to the plurality of first parts and in which the second connector and the third connector are provided, and a plurality of connection parts that connect each of the plurality of first parts and the second part,
wherein the plurality of first parts are disposed on the mounting surface in an overlapping manner by connecting the plurality of first connectors to the plurality of light sources, and
wherein the plurality of connection parts and the second part extend in a direction away from the mounting surface.

8. The light source device according to claim 7,
wherein the plurality of connection parts are arranged at intervals in a width direction of the flexible wire board perpendicular to the arrangement direction of the plurality of first parts and the second part.

9. A light source device, comprising:
a flexible wire board;
a plurality of light sources;
a heat dissipation plate part having a mounting surface on which the plurality of light sources are mounted; and
an optical system attached to the mounting surface,
wherein the flexible wire board has a plurality of wire layers arranged in a thickness direction, and for connecting a plurality of light sources each having a thermistor to a power supply configured to supply power to the light sources and an information processor configured to process information output from the thermistors, the flexible wire board comprising:
a plurality of first connectors for connecting to the plurality of light sources;
a second connector for connecting to the power supply;
a third connector for connecting to the information processor;
a plurality of power supply wires that extend from the plurality of first connectors to the second connector; and
a plurality of signal wires that extend from the plurality of first connectors to the third connector,
wherein the power supply wires and the signal wires are provided in wire layers different from each other,
wherein the flexible wire board includes a plurality of first parts in which the plurality of first connectors are provided in one-to-one correspondence therewith, a second part which is positioned at an interval with respect to the plurality of first parts and in which the second connector and the third connector are provided, and a plurality of connection parts that connect each of the plurality of first parts and the second part,
wherein the plurality of first parts are disposed on the mounting surface in an overlapping manner by connecting the plurality of first connectors to the plurality of light sources, and
wherein the second part is fixed to the optical system.

10. A projector, comprising:
a flexible wire board;
a plurality of light sources;
a power supply;
an information processor; and
a housing in which the flexible wire board, the light source, the power supply, and the information processor are accommodated,
wherein the flexible wire board has a plurality of wire layers arranged in a thickness direction, and for connecting a plurality of light sources each having a thermistor to a power supply configured to supply power to the light sources and an information processor configured to process information output from the thermistors, the flexible wire board comprising:
a plurality of first connectors for connecting to the plurality of light sources;
a second connector for connecting to the power supply;
a third connector for connecting to the information processor;
a plurality of power supply wires that extend from the plurality of first connectors to the second connector; and
a plurality of signal wires that extend from the plurality of first connectors to the third connector,
wherein the power supply wires and the signal wires are provided in wire layers different from each other,
wherein the power supply and the second connector are disposed on the side of a bottom plate part of the housing,
wherein the information processor is disposed on the side of a top plate part of the housing that faces the bottom plate part with respect to the power supply, and
wherein the third connector is disposed on the side of the top plate part of the housing with respect to the second connector.
